(19) United States
(12) Patent Application Publication
(10) Pub. No.: US 2020/0350519 A1
(43) Pub. Date: Nov. 5, 2020

(54) DISPLAY DEVICE AND METHOD OF MANUFACTURING DISPLAY DEVICE

(71) Applicant: Japan Display Inc., Tokyo (JP)

(72) Inventor: Yusuke SASAKI, Tokyo (JP)

(21) Appl. No.: 16/931,566

(22) Filed: Jul. 17, 2020

Related U.S. Application Data
(63) Continuation of application No. PCT/JP2018/040461, filed on Oct. 31, 2018.

(30) Foreign Application Priority Data
Jan. 19, 2018 (JP) 2018-007169

(51) Int. Cl. H01L 51/56; H01L 27/32; H01L 51/52

(52) U.S. Cl. CPC H01L 51/56; H01L 27/3246; H01L 51/0011; H01L 27/3272; H01L 51/5253

(57) ABSTRACT

A display device includes a display area configured by pixels including a light emitting area, and a frame area provided outside the display area. The display device includes a substrate, ribs formed separately in the display area and the frame area and arranged around the light emitting area in the display area and a mask support section that is disposed in the frame area and supports a film formation mask for forming a film at least above the ribs. A top portion of the mask support section is at least 10 μm higher than a top portion of the ribs arranged in the display area in a thickness direction of the substrate.

### CROSS-REFERENCE TO RELATED APPLICATION

The present application is Bypass Continuation of International Application No. PCT/JP2018/040461, filed on Oct. 31, 2018, which claims priority from Japanese Application No. JP2018-007169 filed on Jan. 19, 2018. The contents of these applications are hereby incorporated by reference into this application.

### BACKGROUND OF THE INVENTION

### 1. Field of the Invention

The present invention relates to a display device and a method of manufacturing the display device.

### 2. Description of the Related Art

In a display device such as an organic EL display device, a light emitting layer, an upper electrode, and the like which are included in a display element are formed by vapor deposition using a mask. The display element is sealed with a sealing film. For example, JP 2015-15089 A discloses that a mask is used when forming a cathode electrode. In addition, JP 2017-71842 A discloses that a thin film is formed using a mask having a thick part and a thin part.

Incidentally, in a case of forming a part of the display element by vapor deposition using a mask as described above, there is a case where the mask comes into contact with the display element. At this time, when foreign matter adheres to the mask, the foreign matter is pressed against the display element, and accordingly, there is a case where scratches are generated on the film that configures the display element. In such a case, even when the sealing film is formed on the film where scratches are generated, the sealing film cannot cover the film with unevenness caused by the scratches. Therefore, there is a concern that moisture enters from the location and the display element deteriorates.

### SUMMARY OF THE INVENTION

The present invention has been made in view of the above-described problems, and an object thereof is to provide a display device capable of improving barrier properties of a sealing film.

According to one aspect of the present invention, there is provided a display device. The display device includes a display area configured by pixels including a light emitting area, and a frame area provided outside the display area. The display device includes a substrate, ribs formed separately in the display area and the frame area and arranged around the light emitting area in the display area and a mask support section that is disposed in the frame area and supports a film formation mask for forming a film at least above the ribs. A top portion of the mask support section is at least 10 μm higher than a top portion of the ribs arranged in the display area in a thickness direction of the substrate.

According to another aspect of the present invention, there is provided a display device. The display device includes a display area configured by pixels including a light emitting area, and a frame area provided outside the display area. The display device includes a substrate, ribs formed separately in the display area and the frame area and arranged around the light emitting area in the display area, a mask support section that is disposed in the frame area and supports a film formation mask for forming a film at least above the ribs and a light shielding film disposed at a top portion of the mask support section. The top portion of the mask support section is higher than a top portion of the ribs arranged in the display area in a thickness direction of the substrate.

According to another aspect of the present invention, there is provided a method of manufacturing a display device. The display device includes a display area configured by pixels including a light emitting area, and a frame area provided outside the display area. The method for manufacturing a display device includes the steps of: forming ribs arranged around the light emitting area in the display area and arranged separately in the display area and the frame area, on a substrate; and forming a mask support section that is disposed in the frame area and supports a film formation mask at least above the ribs. The mask support section is higher than the ribs in a thickness direction of the substrate.

### BRIEF DESCRIPTION OF THE DRAWINGS

FIG. 1 is a diagram schematically showing a display device according to an embodiment of the present invention.

FIG. 2 is a diagram for describing a relationship between a large plate and individual substrates.

FIG. 3 is a diagram for describing a section taken along line III-III of the display device.

FIG. 4 is a diagram for describing a section taken along line IV-IV of the display device.

FIG. 5 is a diagram for describing a method of manufacturing the display device.

FIG. 6 is a diagram for describing the method of manufacturing the display device.

FIG. 7 is a diagram for describing the method of manufacturing the display device.

FIG. 8 is a diagram for describing a relationship between a large plate and individual substrates according to a modification.

FIG. 9 is a diagram for describing a section of a display device according to the modification.

### DETAILED DESCRIPTION OF THE INVENTION

Hereinafter, each embodiment of the invention will be described with reference to the drawings. Noted that the disclosure is merely an example, and those skilled in art can easily think of appropriate modifications while keeping the gist of the invention, and the modifications are naturally included in the scope of the invention. Further, in order to make the description clearer, there is a case where the width, thickness, shape, and the like of each part are schematically represented as compared with the embodiment, but these are merely an example, and the interpretation of the invention is not limited thereto. In the specification and the drawings, the same elements as those described above with reference to the drawings already described will be given the same reference numerals, and the detailed description thereof will be appropriately omitted.

Furthermore, in the detailed description of the embodiments of the present invention, when defining the positional relationship between a certain configuration element and another configuration element, the terms “above” and “below” mean not only a case of being positioned immediately above or below the configuration element but also a case where another configuration element is further interposed therebetween unless otherwise specified.

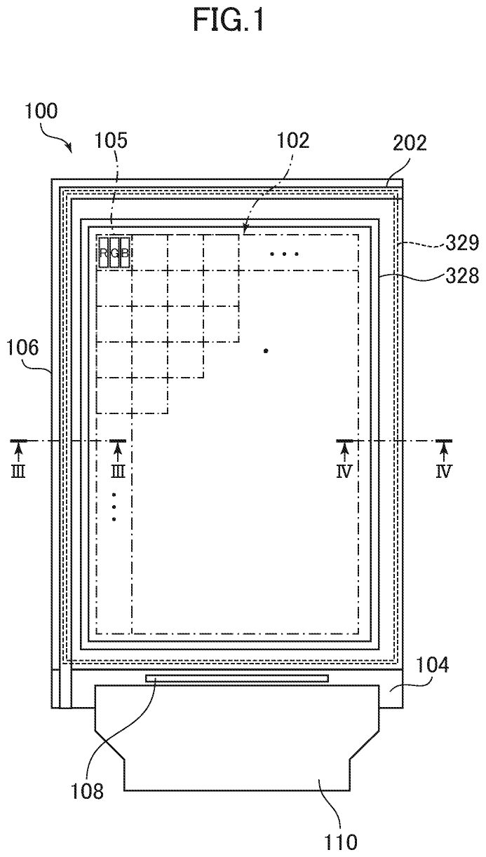

FIG. 1 is a plan view showing an example of a display device 100 according to an embodiment. An organic EL display device is given as an example of the display device 100.

The display device 100 includes a display area 102 and a frame area 104. Specifically, the display area 102 is configured by pixels 105 including the light emitting area. In the display area 102, for example, the pixels 105 configured by combining unit pixels (sub-pixels) of a plurality of colors of red (R), green (G), and blue (B) are arranged in a matrix shape. A full-color image is displayed by the pixels 105. The frame area 104 is provided outside the display area 102. In the display area 102 and the frame area 104, ribs 312 and a flattening film 306 described later are separately formed.

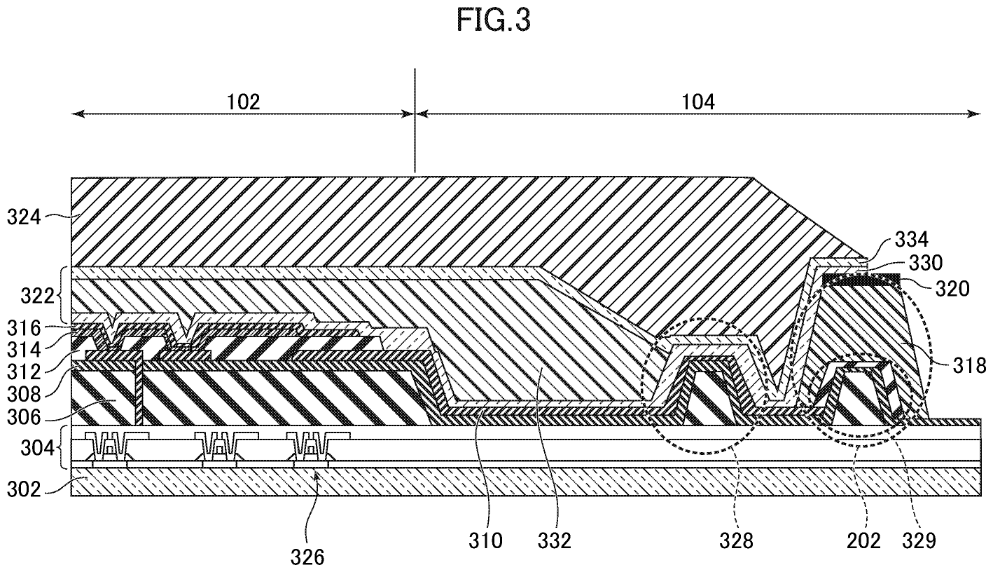

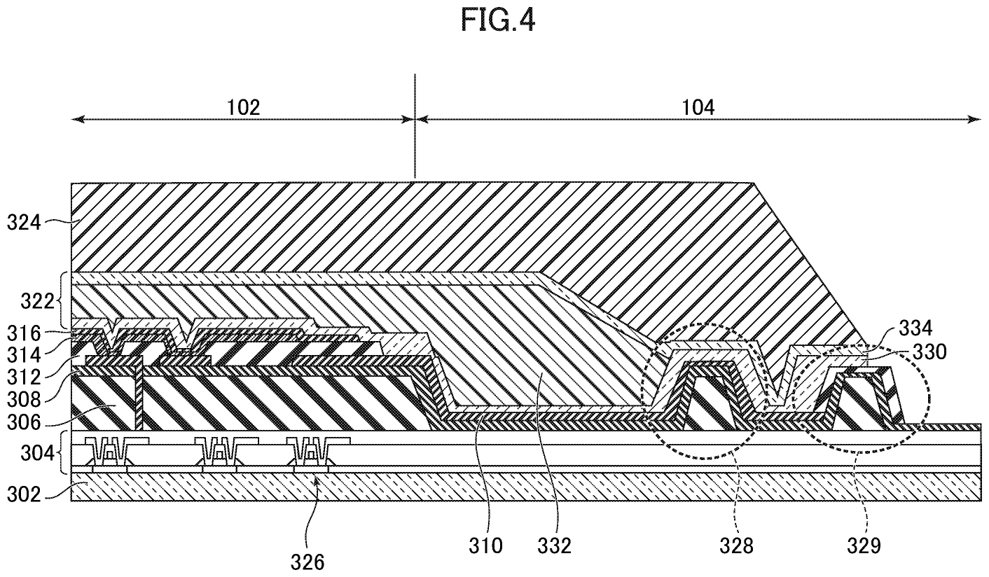

The display device 100 includes a substrate 106, a driving IC 108, and a flexible printed circuit (FPC) 110. The substrate 106 includes the ribs 312 and the like (refer to FIGS. 3 and 4), and the ribs 312 and the like are arranged on a flexible base material 302 such as glass or polyimide. The FPC 110 is disposed in the frame area 104. The FPC 110 supplies power or signals to the circuits formed in the driving IC 108 or the frame area 104. The driving IC 108, for example, applies a potential for conducting between the source and the drain to a scanning signal line of pixel transistors 326 (refer to FIGS. 3 and 4) disposed corresponding to each of the plurality of sub-pixels that configures one pixel 105, and causes a current corresponding to a gradation value of the sub-pixel to flow to each pixel transistor data signal line. By the driving IC 108, the display device 100 displays an image in the display area 102.

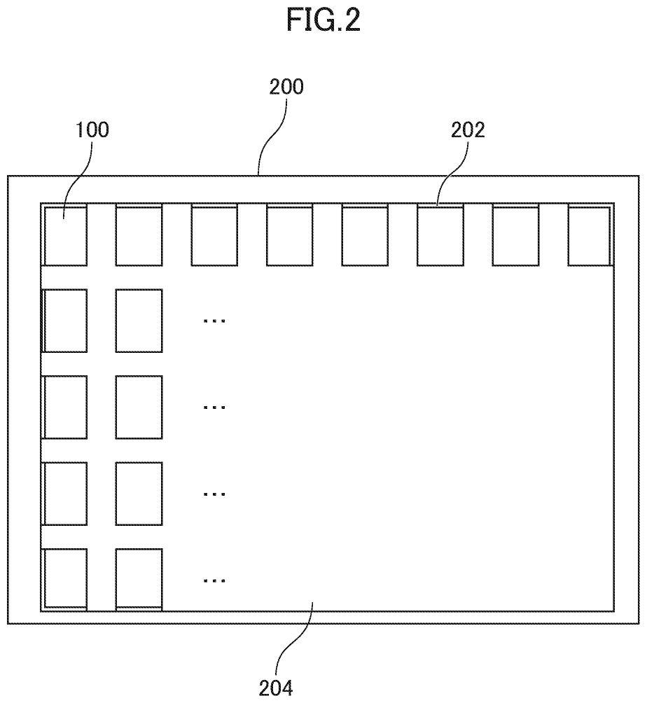

The substrate 106 is the individual substrate 106 cut out from a large plate 200 on which a plurality of the substrates 106 are arranged, and is the substrate 106 disposed on the outermost side of the large plate 200 before being cut out. Specifically, as shown in FIG. 2, a plurality of substrates 106 are arranged on one large plate 200 before being separated. The substrate 106 according to the embodiment is the substrate 106 disposed at the end portion or the corner portion among the plurality of substrates 106 arranged in a matrix shape on the large plate 200.

In addition, a mask support section 202 described later is disposed on the side of the large plate 200 along the end portion. Specifically, the mask support section 202 of the substrate 106 disposed along the left end portion of the large plate 200 in FIG. 2 is disposed along the left side of the substrate 106. The mask support section 202 of the substrate 106 disposed along the upper end portion of FIG. 2 is disposed on the upper side of the substrate 106. The mask support sections 202 at the right and lower end portions are also similarly arranged. The mask support section 202 of the substrate 106 disposed at the upper left corner portion of FIG. 2 is disposed along the upper and left sides of the substrate 106. The mask support section 202 at the other corner portion is also similarly disposed. The substrate 106 shown in FIG. 1 is the substrate 106 disposed at the upper left corner portion of FIG. 2. In addition, the substrates 106 may not be disposed in a matrix shape on the large plate 200. In this case, the substrate 106 is disposed closest to the edge of the large plate 200.

FIG. 3 is a diagram showing a section taken along line III-III of FIG. 1. FIG. 4 is a diagram showing a section taken along line IV-IV of FIG. 1. As shown in FIGS. 3 and 4, the substrate 106 includes a base material 302, a circuit layer 304, a flattening film 306, an inorganic insulating film 308, a lower electrode 310, the ribs 312, an EL layer 314, an upper electrode 316, a mask support film 318, a light shielding film 320, a sealing film 322, and a resin mask 324. The base material 302 is formed of glass or a flexible material such as polyimide.

The circuit layer 304 is configured to include an insulator layer, a source electrode, a drain electrode, a gate electrode, a semiconductor layer, and the like on the upper layer of the base material 302. A transistor 326 is configured by the source electrode, the drain electrode, the gate electrode, and the semiconductor layer. The transistor 326 controls, for example, a current that flows on the EL layer 314 formed in the pixels 105.

The flattening film 306 is formed separately in the display area 102 and the frame area 104. Specifically, the flattening film 306 is formed on the circuit layer 304 in each of the display area 102 and the frame area 104. The flattening film 306 formed in the display area 102 and the flattening film 306 formed in the frame area 104 are separated in a sectional view. The flattening film 306 prevents a short circuit between the lower electrode 310 and an electrode included in the circuit layer 304, and flattens a step due to a wiring disposed on the circuit layer 304 or the transistor 326.

Further, the flattening film 306 is formed separately at two places in the frame area 104. Specifically, in the frame area 104, the flattening film 306 is formed in a projected shape so as to be spaced apart at two places in a sectional view. Of the two flattening films 306 arranged in the frame area 104, the inner flattening film 306 is formed as a part of an inner dam portion 328 that blocks a sealing flattening film 332. The outer flattening film 306 is formed as apart of the mask support section 202 together with the inorganic insulating film 308, the ribs 312, and the mask support film 318. Further, the outer flattening film 306 is formed as a part of an outer dam portion 329 that blocks the resin mask 324 together with the inorganic insulating film 308 and the ribs 312. Both the two flattening films 306 at two places formed on the frame area 104 are formed so as to surround the display area 102 in a plan view. The inner dam portion 328 is formed inside the mask support section 202.

The inorganic insulating film 308 is formed so as to cover the flattening film 306 and the circuit layer 304. The inorganic insulating film 308 is formed of, for example, SiN.

The lower electrode 310 is formed on the inorganic insulating film 308. Specifically, the lower electrode 310 is formed to be electrically connected to the source or drain electrode of the transistor 326 formed on the circuit layer 304 through a contact hole formed on the inorganic insulating film 308 and the flattening film 306 in the display area 102.

The ribs 312 are separately formed on the inorganic insulating film 308 in the display area 102 and the frame area 104. In the display area 102, the ribs 312 are formed around the light emitting area. Specifically, in the display area 102, the ribs 312 are formed so as to surround the area where the EL layer 314 emits light when a current flows between the upper electrode 316 and the lower electrode 310.

The ribs 312 are formed on the flattening film 306 formed outside in the frame area 104. Specifically, in the frame area 104, the ribs 312 are formed on the inorganic insulating film 308 formed on the outer flattening film 306 of the flattening films 306 formed so as to be spaced apart at two places in a sectional view.

The mask support film 318 is formed so as to cover a part of the ribs 312 arranged in the frame area 104. Specifically, as shown in FIG. 3, the mask support film 318 is formed so as to cover the ribs 312 arranged on the side of the large plate 200 along the end portion. In addition, the mask support film 318 is formed such that the top portion of the mask support film 318 is higher than the top portion of the ribs 312 formed in the display area 102. For example, the mask support section 202 is formed with a thickness such that the top portion of the mask support section 202 is at least 10 μm higher than the top portion of the ribs 312 of the display area 102. The mask support film 318 is formed of, for example, SiO or a siloxane-based inorganic insulating film, silicate glass, or the like with a thickness of 200 nm to 1 μm. The mask support section 202 is formed, for example, at a height of 5 to 10 μm from the surface of the base material 302. Note that, as shown in FIG. 4, the mask support film 318 is not disposed around the ribs 312 arranged on the sides other than the side of the large plate 200 along the end portion.

The mask support film 318 configures a part of the mask support section 202. Specifically, the mask support section 202 is configured by the flattening film 306, the inorganic insulating film 308, the ribs 312, and the mask support film 318. The mask support section 202 is formed in the frame area 104 disposed on the side of the large plate 200 along the end portion. The mask support section 202 supports a film forming mask 204 for forming a film at least above the ribs 312. For example, the mask support section 202 supports the mask 204 for forming the EL layer 314.

The EL layer 314 is formed on the lower electrode 310. Specifically, the EL layer 314 is formed on the lower electrode 310 and the end portion of the ribs 312 in the display area 102. The EL layer 314 is formed by stacking a hole injection layer, a hole transport layer, a light emitting layer, an electron injection layer, and an electron transport layer. The light emitting layer emits light by, for example, recombination of holes injected from the lower electrode 310 and electrons injected from the upper electrode 316. Since the hole injection layer, the hole transport layer, the electron injection layer, and the electron transport layer are the same as those in the technique of the related art, the description thereof will be omitted. In the embodiment, the light emitting layer is formed using a material that emits red, green, and blue light.

The upper electrode 316 is formed on the EL layer 314 and causes a light emitting layer included in the EL layer 314 to emit light by causing a current to flow between the upper electrode 316 and the lower electrode 310. The upper electrode 316 is formed of, for example, a transparent conductive film containing a metal such as ITO or IZO or a metal thin film having light transmitting properties and made of AgMg.

The light shielding film 320 is formed at the top portion of the mask support film 318. Specifically, the light shielding film 320 is formed at the top portion of the mask support film 318 with a material that absorbs light. When the mask support film 318 supports the mask 204, there is a case where scratches are generated on the surface of the mask support film 318. The area where the mask support film 318 is formed is an area where no polarizing plate (not shown) for improving visibility is arranged. Therefore, there is a concern that the scratches on the surface of the mask support film 318 are visually recognized from the outside and the display quality is impaired. By disposing the light shielding film 320 that does not transmit light on the mask support film 318, the scratches are unlikely to be visible. Note that the light shielding film 320 may not be provided.

The sealing film 322 is disposed from the display area 102 to the frame area 104 so as to cover the display area 102. Further, the sealing film 322 is configured to include a lower layer barrier film 330, the sealing flattening film 332, and an upper layer barrier film 334. The lower layer barrier film 330 is formed so as to cover the upper electrode 316 and the like from the area where the mask support section 202 is disposed to the display area 102. The sealing flattening film 332 is disposed inside the inner dam portion 328 so as to cover the lower layer barrier film 330. The sealing flattening film 332 flattens the unevenness of the lower layer barrier film 330. The upper layer barrier film 334 is formed so as to cover the lower layer barrier film 330, the sealing flattening film 306, and the like from the area where the mask support section 202 is disposed to the display area 102. The lower layer barrier film 330 and the upper layer barrier film 334 are formed of an inorganic material such as SiN, which does not allow moisture to permeate. The sealing flattening film 332 is formed of acrylic or epoxy, for example. The sealing film 322 can prevent deterioration of the EL layer 314 due to moisture entering the EL layer 314.

The resin mask 324 is formed on the sealing film 322. Specifically, the resin mask 324 is formed of a transparent resin material inside the mask support section 202. The resin mask 324 is a mask for etching the lower layer barrier film 330 and the upper layer barrier film 334.

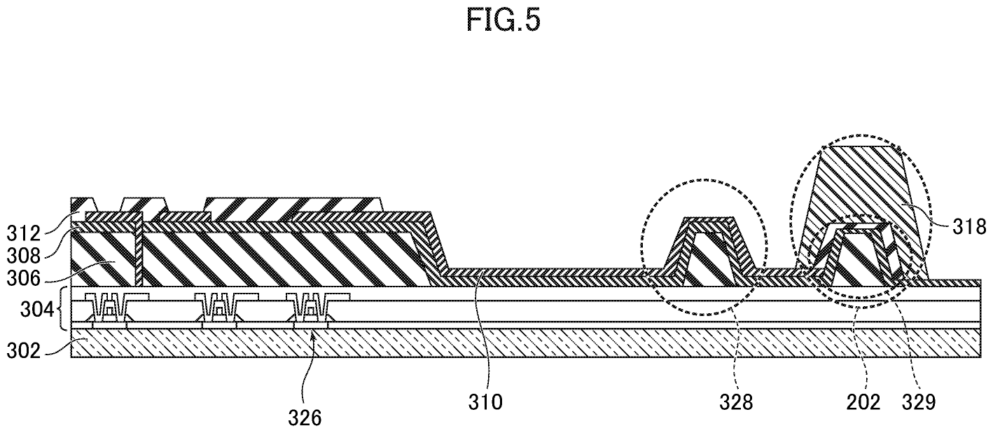

Subsequently, a method of manufacturing the display device 100 will be described. FIGS. 5 to 7 show a method of manufacturing the display device 100. First, as shown in FIG. 5, the circuit layer 304 is formed on the base material 302. Next, the flattening film 306 is formed separately in the display area 102 and the frame area 104. Specifically, the flattening film 306 is formed so as to cover the circuit layer 304 in the display area 102. In addition, the flattening film 306 is formed separately at two places inside and outside the frame area 104. The inner flattening film 306 is a part of the inner dam portion 328, and the outer flattening film 306 is a part of the mask support section 202. Next, the inorganic insulating film 308 and the lower electrode 310 are sequentially formed.

Next, the ribs 312 are formed on the flattening film 306 formed in the frame area 104, and on the inorganic insulating film 308 and the lower electrode 310 of the display area 102. In a case where the ribs 312 of the display area 102 and the ribs 312 of the frame area 104 are formed in the same process, the ribs 312 of the display area 102 and the ribs 312 of the frame area 104 are formed with the same thickness. The ribs 312 of the display area 102 and the ribs 312 of the frame area 104 may have different thicknesses.

Next, the mask support film 318 is formed so as to cover the ribs 312 arranged in the frame area 104. Here, the mask support film 318 is formed to be higher than the ribs 312 formed in the display area 102.

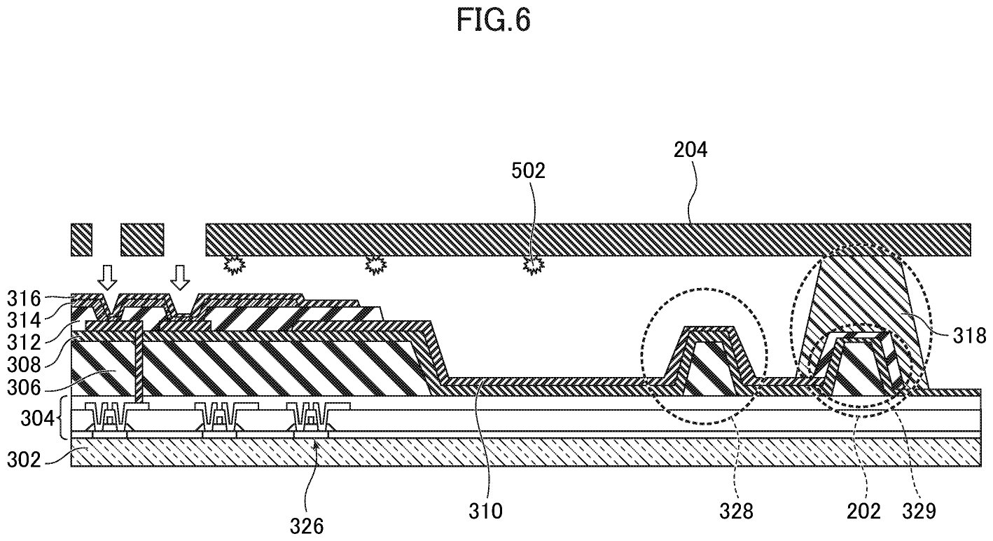

Next, an EL film is formed. Specifically, as shown in FIG. 6, the mask 204 in which a hole is provided in the area that forms the EL layer 314 is disposed so as to be in contact with the mask support section 202. Here, the mask support section 202 is formed with a thickness such that the top portion of the mask support section 202 is higher than the top portion of the ribs 312 of the display area 102. Therefore, even in a case where foreign matter 502 adheres to the mask 204 as shown in FIG. 6, it is possible to prevent the foreign matter 502 from coming into contact with the lower electrode 310 and the like. For example, when the top portion of the mask support section 202 is formed to be at least 10 μm higher than the top portion of the ribs 312 of the display area 102, most of the foreign matter 502 have a size of less than 10 μm, and thus, it is possible to almost prevent a case where scratches are generated on the ribs 312, the lower electrode 310 or the like.

In a plan view, as shown in FIG. 2, the mask 204 has a shape that covers all the substrates 106 arranged on the large plate 200. Specifically, the end portion of the mask 204 coincides with the position of the mask support section 202 formed on each substrate 106 arranged on the outermost side of the large plate 200. In particular, the foreign matter 502 often adheres to the vicinity of the end portion of the mask 204, and a case where the foreign matter 502 adheres to the vicinity of the center portion of the mask 204 rarely occurs. Therefore, even in a case where the mask 204 is curved, it is possible to almost prevent a case where scratches are generated on the ribs 312, the lower electrode 310 or the like.

Similarly, the upper electrode 316 is formed in a state where the mask 204 for forming the upper electrode 316 is disposed so as to be in contact with the mask support section 202.

Next, the mask 204 is removed, and the light shielding film 320 is formed at the top portion of the mask support section 202. The light shielding film 320 is formed of, for example, a material obtained by mixing a metal that absorbs light such as chrome or an organic insulating material such as acrylic or epoxy, with a black pigment. There is a case where scratches are generated at the top portion of the mask support section 202 by coming into contact with the mask 204. The light shielding film 320 can prevent the scratches from being visually recognized from the outside.

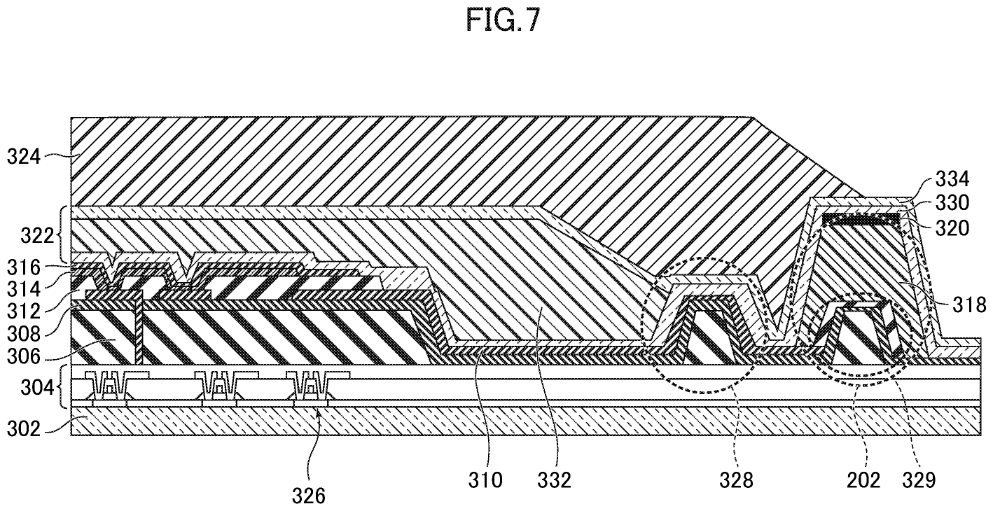

Next, as shown in FIG. 7, a lower layer barrier film 330 is formed so as to cover the entire substrate 106. Further, the sealing flattening film 332 is applied to the display area 102. Since the sealing flattening film 332 is in a liquid state, the sealing flattening film 332 flows from the display area 102 toward the frame area 104, but is blocked by the inner dam portion 328. Accordingly, the inside of the inner dam portion 328 is filled with the sealing flattening film 332. The liquid sealing flattening film 332 is cured by being irradiated with ultraviolet rays. The upper layer barrier film 334 is formed on the sealing flattening film 332 so as to cover the entire substrate 106.

Next, the resin mask 324 is formed on the upper layer barrier film 334. The resin mask 324 is formed such that the end portion of the resin mask 324 is positioned on the outer dam portion 329 or at the top portion of the mask support section 202. Next, the upper layer barrier film 334 and the lower layer barrier film 330 are etched. Here, the resin mask 324 functions as an etching mask, and thus, a part of the upper layer barrier film 334 and the lower layer barrier film 330 that are not covered with the resin mask 324 are removed. Finally, the individual substrates 106 are cut out from the large plate 200 in the state shown in FIG. 2. Accordingly, the display device 100 is brought into the state shown in FIGS. 3 and 4.

As described above, by forming the mask support film 318 higher than the ribs 312, which are formed in the display area 102, in the frame area 104, the barrier properties of the sealing film 322 can be improved.

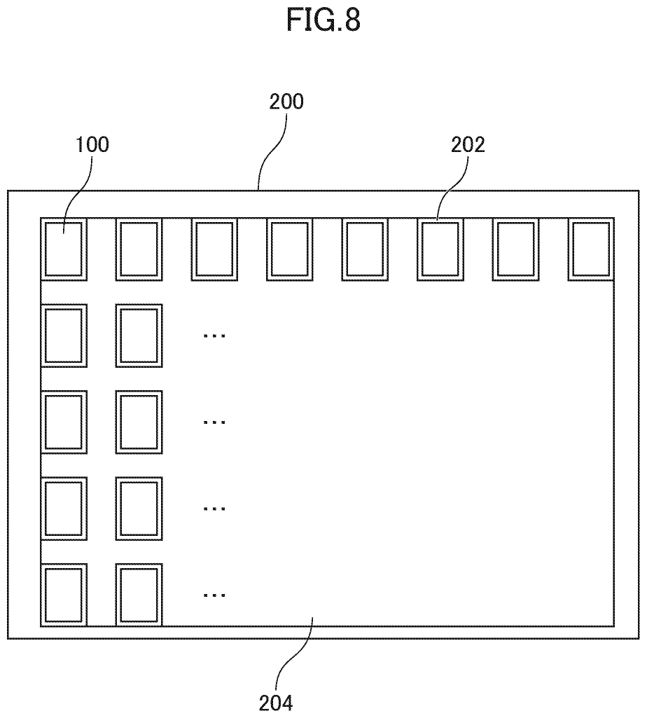

In the above, a case where the mask support section 202 is disposed on the side of the large plate 200 along the end portion has been described, but the embodiment of the invention is not limited thereto. For example, as shown in FIG. 8, the mask support section 202 may be configured to be formed at the end portion of each substrate 106 arranged on the large plate 200. According to the configuration, the mask 204 is in contact with the mask support section 202 not only at the end portion but also at the center portion, and thus, the mask 204 is unlikely to be curved. Accordingly, the distance between the mask 204 and the display area 102 is kept constant, and it is possible to further reduce the possibility that scratches are generated on the ribs 312, the lower electrode 310 or the like by the foreign matter 502.

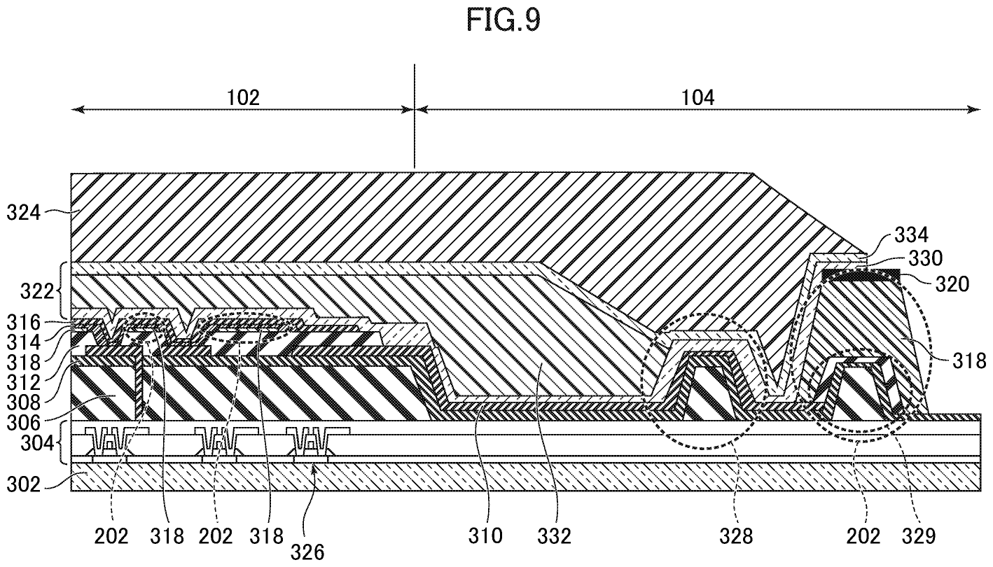

Further, the mask support film 318 may be further formed in the display area 102. Specifically, for example, as shown in FIG. 9, the mask support film 318 may be further formed on the ribs 312 provided in the display area 102. According to this configuration, the mask support section 202 is also formed in the display area 102. Accordingly, even in a case where the mask 204 is curved, it is possible to prevent scratches of the ribs 312 or the lower electrode 310 from being generated as the mask support section 202 formed in the display area 102 supports the mask 204. In addition, in the modification, the height of the mask support section 202 formed in the display area 102 is preferably lower than the height of the mask support section 202 formed in the frame area 104.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a substrate;
a display area configured by pixels including a light emitting area, and a frame area provided outside the display area;
ribs formed separately in the display area and the frame area and arranged around the light emitting area in the display area; and
a mask support section that is disposed in the frame area and supports a film formation mask for forming a film at least above the ribs, wherein
a top portion of the mask support section is at least 10 μm higher than a top portion of the ribs arranged in the display area in a thickness direction of the substrate.

2. The display device according to claim 1, wherein
the substrate is an individual substrate cut out from a large plate on which a plurality of the substrates are arranged, and is a substrate disposed at an end portion or a corner portion of the large plate before being cut out.

3. The display device according to claim 1, further comprising:
a light shielding film for shielding light disposed at the top portion of the mask support section.

4. The display device according to claim 1, further comprising:
a sealing film that covers the display area; and
a dam portion formed in the frame area so as to surround the display area, wherein
the dam portion is disposed inside the mask support section.

5. The display device according to claim 4, further comprising:
a resin mask provided on the sealing film.

6. A display device comprising:
a substrate;
a display area configured by pixels including a light emitting area, and a frame area provided outside the display area;
ribs formed separately in the display area and the frame area and arranged around the light emitting area in the display area;
a mask support section that is disposed in the frame area and supports a film formation mask for forming a film at least above the ribs; and
a light shielding film disposed at a top portion of the mask support section, wherein
the top portion of the mask support section is higher than a top portion of the ribs arranged in the display area in a thickness direction of the substrate.

7. The display device according to claim 6, wherein
the substrate is an individual substrate cut out from a large plate on which a plurality of the substrates are arranged, and is a substrate disposed at an end portion or a corner portion of the large plate before being cut out.

8. The display device according to claim 6, further comprising:
a sealing film that covers the display area; and
a dam portion formed in the frame area so as to surround the display area, wherein
the dam portion is disposed inside the mask support section.

9. The display device according to claim 8, further comprising:
a resin mask provided on the sealing film.

10. A method of manufacturing a display device, the display device comprising:
a display area configured by pixels including a light emitting area, and a frame area provided outside the display area,
the method comprising steps of:
forming ribs arranged around the light emitting area in the display area and arranged separately in the display area and the frame area, on a substrate; and
forming a mask support section that is disposed in the frame area and supports a film formation mask at least above the ribs, wherein
the mask support section is higher than the ribs in a thickness direction of the substrate.

11. The method according to claim 10, wherein
the top portion of the mask support section is formed at least 10 μm higher than the top portion of the ribs arranged in the display area in the thickness direction of the substrate.
